(19) United States
(12) Patent Application Publication
(10) Pub. No.: US 2026/0181982 A1
(43) Pub. Date: Jun. 25, 2026

(54) FIN PROFILE MODULATION FOR DUMMY GATE GAPFILL

(71) Applicant: Taiwan Semiconductor Manufacturing Company, Ltd., Hsinchu (TW)

(72) Inventors: Ming-Feng Hsieh, New Taipei City (TW); Hsueh-Chang Sung, Hsinchu City (TW); De-Wei Yu, Hsinchu City (TW); Hung-Yao Chen, Hsinchu City (TW)

(73) Assignee: Taiwan Semiconductor Manufacturing Company, Ltd., Hsinchu (TW)

(21) Appl. No.: 18/990,165

(22) Filed: Dec. 20, 2024

(51) Int. Cl. H10D 64/01; H10D 30/01

(52) U.S. Cl. CPC H10D 64/017; H10D 30/014; H10D 30/0195

(57) ABSTRACT

A fin profile modulation method includes forming a pair of channel structures with sidewalls along a first lateral direction of a semiconductor device, a profile of the sidewalls modulating a position of a first void in a gate material deposited thereover. The method includes depositing the gate material over the channel structures to envelop the first void. The method includes patterning, perpendicular to the first lateral direction, the gate material to form a plurality of dummy gate structures comprising a plurality of second voids corresponding to portions of the first void. The method includes depositing a spacer material over the semiconductor device, and into the plurality of second voids. The dummy gate structures are removed to form openings defined by the spacer material, the openings comprising a remaining portion of the spacer material. The method includes forming an active gate structure in the opening.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. More recently, improvements to device density increasingly relate to three dimensional features, such as the formation of fins or nanostructures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor device including a void defined by a gate material, in accordance with some embodiments.

FIG. 2 illustrates a perspective view of a semiconductor device including dummy gates formed by patterning the gate material, the dummy gates including voids corresponding to the void of FIG. 1, in accordance with some embodiments.

FIG. 3 illustrates a cross sectional view of a semiconductor device including a remaining portion of a spacer material, in accordance with some embodiments.

FIGS. 4, 5, 6, 7, and 8 illustrate cross sectional views of various semiconductor devices and a corresponding position of voids, in accordance with some embodiments.

FIG. 9 illustrates a flow chart for a method for fabricating a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Non-planar semiconductor devices can include non-lateral (e.g., vertical) features, such as channel structures. For example, these channel structures can include fins of a finFET or nanostructures of a gate all-around (GAA) transistor, such as a fork sheet transistor. Manufacturing the semiconductor devices can include depositing materials over the surface of such non-lateral features. For example, a gate material may be deposited over channel structures protruding from a lateral surface. The gate material can thereafter be patterned to form a dummy gate structure, and subsequently replaced with an active gate structure. In some cases, the deposited gate material can include defects such as voids. For example, a void may form between closely spaced fins or other non-lateral structures, according to at least some deposition processes. For example, a trench can form parallel to and between two parallel fins or nanostructures. If the void (e.g., the trench) remains fully enclosed until the dummy gate is replaced with an active gate structure, the presence of the void may not impact a finished semiconductor device.

In some cases, operations performed subsequent to the formation of the dummy gate structure and prior to the replacement of the dummy gate with an active gate can deposit a spacer material into the voids. For example, the gate material of the dummy gate may be patterned to define individual dummy gate structures (e.g., one for each channel structure). A spacer layer formed over the dummy gate structures prior to a formation of an inter-layer dielectric (ILD), or the ILD itself, can fill the voids. A portion of the spacer material may form in the void. In some embodiments, the ILD or other material is formed absent a separate spacer layer, in which case the ILD material may itself occupy any voids of the dummy gate structure. For brevity of the disclosure, the terminology of a “spacer” or “spacer material” will be used to refer to the ILD itself, a separate spacer, hardmask, or other material spacing the dummy gate structures from one another, as may occupy the voids of the dummy gate structures. In some cases, such a spacer material may remain subsequent to the removal of the dummy gate (e.g., because an etchant which is selective to the gate material, relative to the spacer may be selected to remove the dummy gate while preserving the dimensions thereof for an active gate structure).

The geometry of the voids may correspond to the profile of opposing sidewalls of non-lateral features of the semiconductor device (e.g., the fins or nanostructures). According to the present disclosure, various geometries of the lateral features and their sidewalls are provided to modulate the position, size, and presence of the voids (and thus modulate the position, size, or presence of a spacer material formed in the voids). For example, the various geometries provided herein can modulate the position of the remaining spacer. Such modulation can aid to remove the spacer via a flush process, or otherwise modulate a complete semiconductor device (e.g., by controlling a channel geometry).

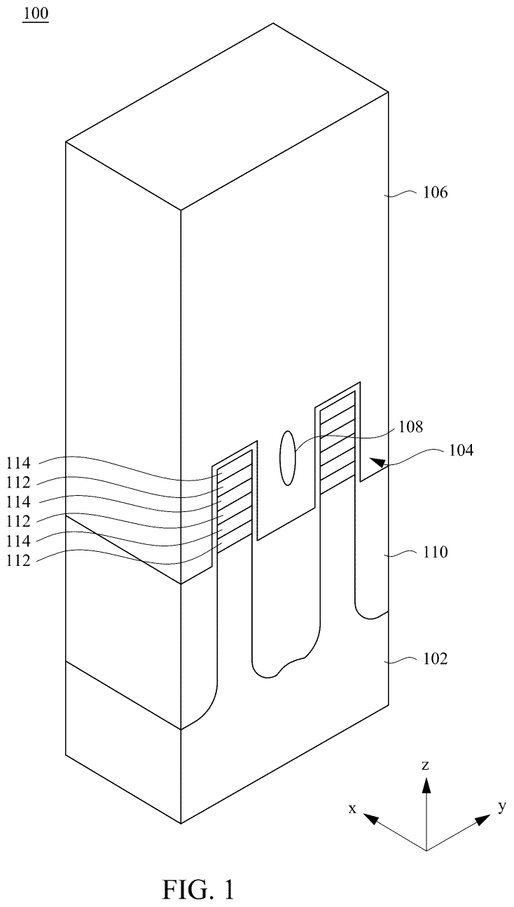

FIG. 1 illustrates a perspective view of a semiconductor device 100 including a void 108 defined by a gate material 106, in accordance with some embodiments. The semiconductor device 100 includes a substrate 102. The substrate 102 can include (e.g., be comprised substantially of) a semiconductor material such as silicon, germanium, gallium arsenide, or so forth. In some embodiments, a silicon substrate is provided with a (100) or (110) crystallographic orientation, as may aid in the mobility of electrons traversing various implementations of channel structures 104. The depicted semiconductor substrate 102 extends to the channel structures 104. For example, the channel structures 104 can include a fin of a finFET. In some embodiments, the substrate may not extend to the channel structure 104 (e.g., the channel structure 104 may be isolated from a substrate 102).

Each channel structure 104 can include one or more semiconductor portions. For example, in some embodiments, the channel structure 104 is a monolithic silicon channel. In some embodiments, the channel structure 104 includes multiple portions, such as alternating semiconductive layers 112 and sacrificial layers 114 of a nanostructure to form a GAAFET. For example, the channel structure 104 can include alternating semiconductive layers 112 of silicon channels and silicon germanium as a sacrificial material of the sacrificial layers 114. In some embodiments, the channel structure 104 can include alternating semiconductive layers 112 of silicon-germanium (SiGe) channels (e.g., between about twenty percent and about sixty percent germanium) and further sacrificial layers 114, as typically include a higher germanium content (e.g., about eighty percent). In some embodiments, the channel structure 104 can include nanostructures formed from stacked nanosheets of the alternating layers 112, 114. For example, the layer can include one pair of alternating layers 112, 114, four pairs of alternating layers, or additional alternating layers 112, 114.

According to the depicted semiconductor device 100, shallow trench isolation (STI) regions 110 are provided between the channel structures 104, with the channel structures 104 protruding therefrom. Accordingly, although the sidewalls of the vertical features may extend somewhat below the gate material 106, such geometry may not impact the formation of the void 108 in the same way as the channel structure 104 disposed along lower surface (relative to a vertical direction 99C) of a junction between the gate material 106 and the channel structures 104. In some embodiments, a further layer (e.g., an etch stop layer, gate oxide, or so forth) can separate the gate material 106 from the channel structures 104 or the STI region 110. The further layer may be formed over the semiconductor device 100 prior to depositing the gate material 106. For example, the further layer can be deposited according to an atomic layer deposition (ALD) or other process for form a blanket film (e.g., Chemical Vapor Deposition, CVD; Physical Vapor Deposition (PVD); spin coating; etc.).

Referring more particularly to the depicted void 108, the depicted portion of the void is depicted along a front cut face parallel to a second lateral direction (Y) of the provided axis. The void 108 extends into the sheet (along a first lateral direction (X) perpendicular to the first lateral direction). Such a void may be referred to as a trench, although the cross section of such a trench can vary along the first lateral direction (X), corresponding to variations of the sidewalls of the channel structures 104, deposition of the gate material 106, or so forth. The gate material 106 can be removed to form an opening in which an active gate structure is formed. For example, the gate material 106 can include or consist essentially of amorphous silicon (a-Si) as may lead to incomplete filling in narrow or high aspect ratio features such as between the depicted channel structures 104. Such an example should not be construed as limiting. Further gate materials 106 can include polycrystalline silicon (poly), silicon dioxide (SiO₂), silicon nitride (Si₃O₂), or spin on glass (SOG), in some embodiments.

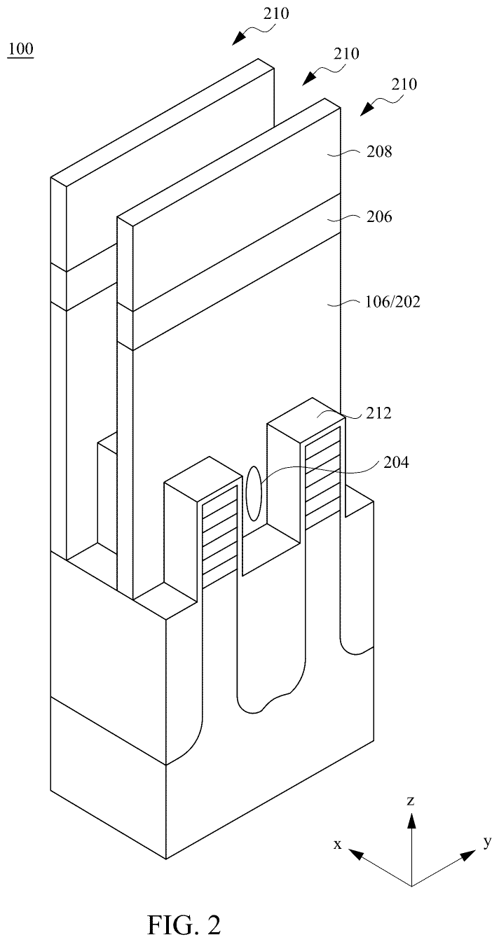

FIG. 2 illustrates a perspective view of the semiconductor device 100 including dummy gate structures 202 formed by patterning the gate material 106, the dummy gate structures 202 including voids 204 corresponding to the void 108 of FIG. 1, in accordance with some embodiments. The openings include a first opening 210 (depicted as a front opening 210), second opening 210 (depicted as a middle opening 210) and third opening 210 (depicted as a rear opening 210). The various openings 210 are depicted as spaced between the dummy gate structures 202. In some embodiments, additional openings 210 can be formed between additional portions of the gate material 106 to form further dummy gate structures 202. Such further openings 210 can include openings 210 formed along the first lateral direction (X), so or perpendicular thereto, along the second lateral direction (Y). In some embodiments, spacers are formed along either of the first lateral direction (X) or the second lateral direction (Y) to separate transistors of a semiconductor device 100.

As can be observed in openings 210 patterned between the dummy gate structures, the further layer 212 (e.g., spacer or gate oxide) described with regard to FIG. 1 is depicted separating the channel structures 104 from the dummy gate structures 202. The further layer 212 can include or operate as etch stop layer or gate oxide, as described above.

The present disclosure contemplates patterning the gate material according to various techniques such as positive or negative photoresists, e-beam lithography, focused ion beam, or so forth. Accordingly, the illustrative example of a positive photoresist process provided henceforth should not be construed as limiting. According to an illustrative example, a patterning mask 206 (e.g., silicon nitride, SiN) is provided over the gate material 106 with an oxide layer 208 formed thereover. A photoresist is applied, and a photolithographic process is performed to remove at least the SiN and, in some embodiments, a portion of gate material 106 underneath. Another etchant (e.g., directional etchant or other an-isotropic process) can thereafter remove the unmasked portion of the gate material 106. The removal of the gate material 106 can define the depicted dummy gate structure 202 alternating with the depicted openings 210 therebetween. That is, the dummy gate structures 202 refers to the non-removed portions of the gate material 106, as masked by the patterning mask 206, while the openings 210 refer to the removed (unmasked) portions. Accordingly, removing the gate material 106 to form the openings 210 can partition a generally trench shaped void 108 for form various shorter voids 204, (e.g., one or more in each of the dummy gate structures 202).

The depicted void 204 can be similar to the void of 108 of FIG. 1 along the cut plane of the present view. Like the void 108 of FIG. 1, the present void 204 may be generally trench-shaped so as to extend along the first lateral direction (X) of the provided axis. But unlike the void 108 of FIG. 1, the presently depicted void terminates at openings 210 at opposite ends of the dummy gate structures 202. Accordingly, any subsequent processes can cause further material to form in the void 204. For example, a deposition process for a hardmask, ILD, or other spacer layer can deposit the hardmask, ILD, or other spacer material into the voids 204, along with the openings 210. Some illustrative examples of spacer materials include silicon nitride (SiN), silicon oxycarbide nitride (SiCON), or silicon carbonitride (SiCN), or combinations thereof, among others.

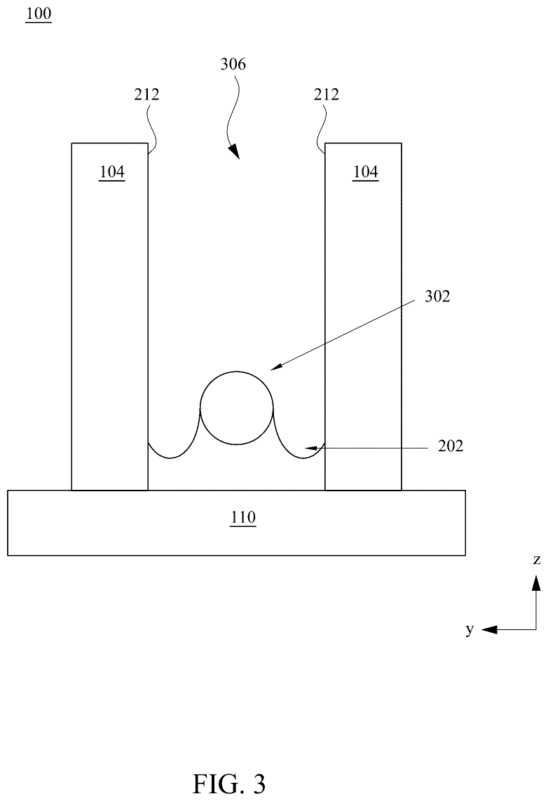

In some embodiments, an etchant or other process used to remove the dummy gate structure 202 may be selective the gate material (e.g., a-Si) relative to the spacer material occupying the void 204. Indeed, the spacer material and the etchant may be selected for removal of the dummy gate structures 202 without removing the spacer layer (e.g., a layer separating the openings 210 from the dummy gate structures), so as to define another opening for an active gate structure according to the dimensions of the dummy gate structure. According to such a sequence, a portion of the spacer material formed in the void 204 may remain in the void during subsequent operations, even where all or a substantial portion of the dummy gate structure has been removed. Further, as depicted henceforth with regard to, for example, FIG. 3, the presence of the spacer material in the void 204 can inhibit removal of the dummy gate process by making portions of the dummy gate structure below the spacer material protected from removal. The presence, size, location, and geometry of a remaining portion of the spacer material can impact further operations such as forming an active gate (e.g., a metal gate or poly gate).

FIG. 3 illustrates a cross-sectional view of a semiconductor device 100 including a remaining portion of a spacer material 302, in accordance with some embodiments. The depicted cross-sectional view is along a cut plane parallel to the second lateral direction (Y). An opening 306 is bound laterally by the channel structures 104 and vertically, along a lower surface with the semiconductor device 100 (e.g., an STI region 110). This opening 306 should not be conflated with the opening 210 of FIG. 2. The openings 210 of FIG. 2 is laterally offset from the depicted view, along the first lateral direction (X) (e.g. into and out of the page). In some embodiments, however, the president opening 306 and the opening 210 of FIG. 2 can share dimensions along a vertical direction (Z) and second lateral direction (Y). Further, as described above, the opening 210 of FIG. 2 may be filled with a spacer, ILD, or so forth prior to the formation the depicted opening 306 (as may be formed via the removal of the dummy gate structure 202).

This cross-sectional view depicts the semiconductor device 100 subsequent to the removal of the dummy gate structure 202, where such a removal is inhibited by the remaining portion of the spacer material 302. That is, the opening 306 is generally coextensive with the dummy gate structure 202 of FIG. 2, with some deviation in dimensions due to the remaining gate material 106 of the dummy gate structure 202.

According to the depicted view, a remaining portion of spacer material 302 is depicted between the adjacent channel structures 104. Since an etching or other process used to remove the dummy gate structure 202 to define the opening 210 is selective to a-Si or other gate material 106, relative to the portion of spacer material 302, the spacer may mask a portion of the gate material 106 so as to prevent its removal. In some embodiments, a further layer 212 of the sidewalls of the channel structures 104 can prevent removal of the channel structure 104 with the dummy gate structure 202 (e.g., where the gate material 106 and the channel structure 104 are both silicon). In some embodiments, the removal of the dummy gate structure 202 may be according to a process which does not remove (or does not substantially remove) an exposed material of the channel structures 104. Further, in some embodiments, further operations may be performed such as etching back alternating portions of the channel structure 104 to define various semiconductive channels (e.g., removing germanium portions of a silicon and germanium nanostructure).

When an active gate structure is formed in the opening 210, the spacer material 302 (generally a dielectric material), and the a-Si or other gate structure can remain in the final gate structure. Such features can impact the operation of a component (e.g., transistor or diode) of the semiconductor device 100. For example, the reduced surface area of contact between the active gate and the channel structure 104 can lower the overall drive current and transconductance of the component, increase threshold voltages, increase subthreshold leakage, and otherwise modulate component performance. Moreover, such effects can vary over the surface of a device, based on the variation of the sidewalls of the channel structures 104, deposition of the gate material 106, deposition of the spacer material, and so forth (e.g., corresponding to a variation of dimensions of the void 204).

According to various aspects of the present disclosure, various sidewall geometries are provided, as may modulate a position and geometry of the remaining portion of spacer material 302. Such a position and geometry may, in turn, modulate the formation of an active gate in the depicted opening 306. For example, the active gate structure may be formed over the remaining portion of spacer material 302 or the remaining portion of spacer material 302 can be removed prior to a formation of the active gate structure.

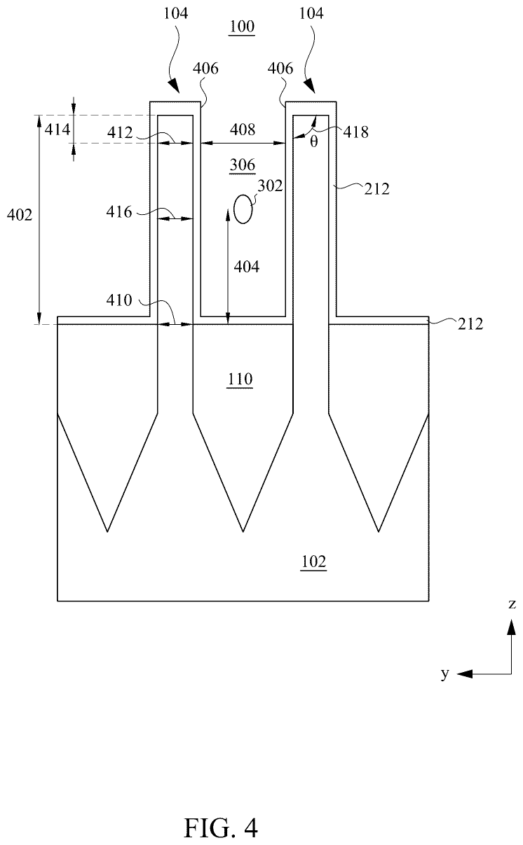

FIGS. 4, 5, 6, 7 and 8 illustrates a cross sectional view of various semiconductor devices 100 and a corresponding position of a remaining portion of the spacer material 302, in accordance with some embodiments. A void 204 can define a position and size for the remaining portion of a spacer material 302. The remaining portion of the spacer material 302 can impact dummy gate structure 202 removal. However, such a remaining portion can substantially vary according to a type, duration, or isotropy of a process used to remove the dummy gate structure. Accordingly, an opening 306 corresponding to the geometry of the dummy gate structure 202 is depicted without any residual portion of the gate material 106 to aid with the clarity of the figures.

The sidewall profiles depicted in FIGS. 4-8 may be formed according to various techniques. Some illustrative examples are provided henceforth. In some embodiments, a relatively isotropic or anisotropic etchant may be used to relative negative or positive taper of the sidewalls. In some embodiments, the profile is generated according to a sequence of suboperations, such as use of one etchant (or environmental conditions of a chamber) for a lower portion of the sidewalls, and a modified etchant (or environmental conditions of the chamber) for an upper portion of the sidewalls. In some embodiments, a portion of the sidewall may be passivated to generate a re-entrant or tapered profile. These examples should not be construed as limiting. One familiar with the art will recognize numerous further techniques that can be employed to generate various sidewall profiles, including the sidewall profiles depicted herein.

As is illustrated in FIG. 4, and referring generally to each of FIGS. 4, 5, 6, 7, and 8, the depicted channel structures 104 can include silicon (Si) fins, germanium containing fins such as silicon-germanium (SiGe) fins, or various nanosheets as discussed above. The channel structures 104 can exhibit a width (e.g., each of a first width 410, second width 412 and third width 416 along the second lateral direction (Y)) of between about 6 (six) nanometers (nm) and about 100 (one-hundred) nm. The channel structures 104 can exhibit a height 402 (along the vertical direction (Z)) of between about 30 (thirty) nm and about 100 (one hundred nm), as measured from a protrusion of the channel structures 104 from a substrate 102, STI region 110, further layer 212, or other lower bound for the opening 306 (e.g., corresponding to the dummy gate structure 202). A spacing between channel structures (e.g., inter-fin spacing 408) can measure between about 10 (ten) nm and about 70 (seventy) nm. As discussed above, although such dimensions may provide dense devices, the narrow or high aspect ratio features can lead to void formation, resulting in the remaining portion of a spacer material 302. A size, shape, and position of such a remaining portion of the spacer material 302 may be modulated according to various sidewall geometries for the channel structures 104, some examples of which are provided henceforth.

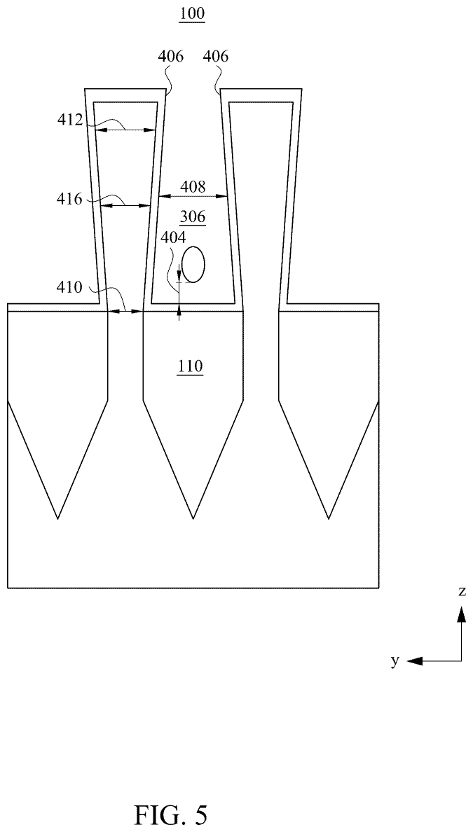

For example, with particular reference to FIG. 4, a height 404 for the remaining portion of a spacer material 302 is about half of the height 402 of the channel structures 104. Such a position of the spacer material 302 can correspond to a substantially vertical sidewall of the channel structures 104. For example, a first width 410 of the channel structures 104 extends a first distance along the second lateral direction (X) at a first position in the vertical direction (Z), the first position being a lowermost position of the first, second and third position. The third position may be disposed along a surface of a lateral plane at an upper surface of an STI region 110, in some embodiments, or otherwise within a bottom third of the protruding portion of the channel structures 104 (e.g., where the channel structures 104 protrudes above the STI region 110). However, a portion of the channel structures 104 can continue to extend below the first position (e.g., towards a substrate, as the channel structures 104 may be coupled with). The first width 410 is approximately equal to a second width 412 a second distance along the second lateral direction (Y) at a second, uppermost position along the vertical direction (Z) (e.g., within five nm of the upper surface of the channel structure or otherwise within an upper third of the protruding portion of the channel structures 104). Although referred to as an uppermost portion, the second width 412 can be measured as offset 414 somewhat below an upper surface of the channel structure 104 to avoid measurement error due to a radius of curvature of a fin structure or other channel structure 104. For example, the second width 412 (for FIG. 4 as well as FIGS. 5-9) can refer to a width taken at an offset 414 of less than five nm from the top of the channel structure 104. Accordingly, the second width 412 can avoid curved upper corners as may be provided with a radius of curvature of, for example, about a half of one nm (that is, 1/Rfᵢₙ<2 nm⁻¹). In some embodiments, such as those including substantially rectangular channel structures 104 (e.g., with an upper fin angle 418 of between 80 (eighty) and 100 (one hundred degrees)), the second width 412 can correspond to the upper surface of the rectangular fin or nanostructure. A third width 416 is disposed about along the vertical direction (Z) between the first width 410 and second width 412 (e.g., at or proximate to a vertical center of the channel structure 104, sometimes referred to as medially disposed). For example, the third width 416 can be located within a central third of the protruding portion of the channel structures 104.

Referring back to the height 404 for the remaining portion of a spacer material 302, the height 404 can be closer to a vertical position of the third width 416 than a vertical position of either of the first width 410 or the second width 412. Each of the first width 410, second width 412, and third width 416 can be about equal to one another, to form a substantially vertical sidewall 406. This sidewall profile may be associated with formation of the remaining portion of a spacer material 302 in another (e.g., medial) portion of the opening 306.

The channel structures 104 of FIG. 4, (and FIGS. 5-9, henceforth) are substantially symmetrical about the second lateral direction (Y). Accordingly, the spacing 408 between adjacent paired fin structures, for an equal first width 410, second width 412, and third width 416, is also equal at the vertical positions corresponding to each of the first width 410, second width 412 and third width 416. In some embodiments, where the channel structures 104 are not substantially symmetrical, the various widths can vary to maintain the equidistant spacing of the spacing 408 between various vertical positions of the respective channel structures 104.

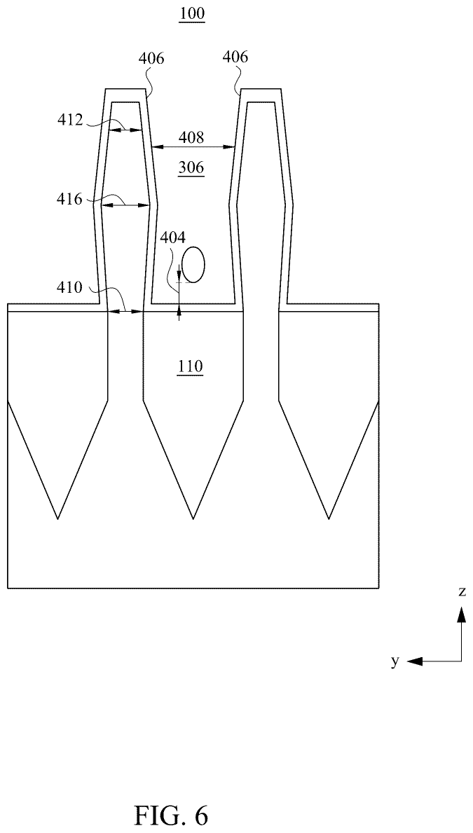

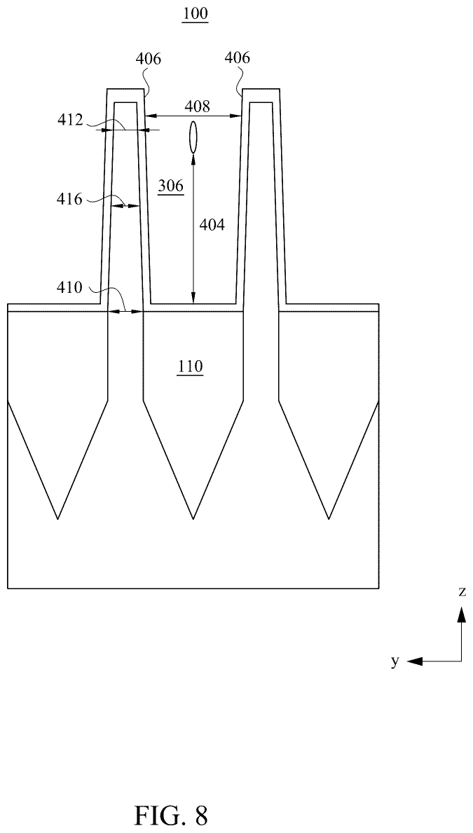

The remaining portion of a spacer material 302 can form in various positions between the depicted channel structures 104. For example, spacer material 302 can concentrate about a geometric center of the opening 306. Such a position can provide at least a portion of the opening 306 above the spacer material 302 unmasked to ensure an active gate formed in the opening 306 contacts at least some portions of channel structure 104. Further, the position of the spacer material 302 well above the bottom of the opening 306 can aid in the removal of the spacer material 302 in some embodiments, at least relative to the sidewalls 406 of FIG. 5 or FIG. 6. For example, a flush process can evacuate the spacer material 302, in some embodiments. Such an evacuation can be aided by under-etch as may be more completely realized than in instances where the spacer material 302 forms somewhat lower in the opening (e.g., as is depicted in FIG. 5 or FIG. 6). The under etch (under the spacer material 302) may be somewhat less than in FIG. 8, since the entrant angle of an etching to under etch the spacer material 302 will be steeper than for the spacer material 302 of FIG. 8. However, unlike FIG. 8, non-removal of the spacer can still provide removal of a substantial portion of the dummy gate structure 202, such that an active gate structure will contact (via a gate oxide) more of the area of the channel structures 104 than for the semiconductor device of FIG. 8, if the spacer material 302 is not flushed or otherwise removed.

Referring now to FIG. 5, the sidewalls 406 of channel structures 104 defining an opening 306 therebetween exhibit negative taper, so that the opening 306 is wider at the bottom than at the top. In some embodiments, the spacing 408 between the pair of channel structures 104 decreases monotonically from bottom to top. More particularly, for the depicted symmetrical sidewalls 406, the first width 410 and the third width 416 are less than the second width 412. The first width 410 is less than the third width 416. Accordingly, a width of the opening (e.g., inter-fin spacing 408) can be greatest at a same vertical dimension of the first width 410, least at the same vertical dimension as the second width 412 and medial at the same vertical dimension as the third width 416.

Such a geometry of the opening 306 can cause the formation of voids 204 and a remaining portion of a spacer material 302 in such voids at a wider portion of the opening 306, as the deposition of the gate material 106 kinks off the void 204 during a deposition process. That is, the height 404 of the remaining portion of a spacer material 302 can be disposed between the vertical height for the first width 410 and the vertical height for the third width 416.

Relative to FIG. 4, the reduced height 404 of the spacer portion 302 (as may be caused by the gate material 106 kinking lower than in FIG. 4) can provide a greater portion of the sidewalls 406 above the remaining portion of the spacer material 302. Accordingly, where the spacer material 302 is not removed, an active gate deposited over the spacer material 302 can benefit from increased contact area with the channel structures 104. Further, according to an increased lateral dimension of the opening 306 at the location of the spacer material 302, it may ease the ingress of an etchant (e.g., with a wet or other isotropic etch), as may improve a removal rate for the spacer material 302 (e.g., according to a flush as may be performed after or during an etching operation.). Moreover, the geometry may avoid formation of spacer material 302 at an upper edge of the channel structure 104, as may inhibit landing contacts, MD structures, or other components.

Referring now to FIG. 6, sidewalls 406 of channel structures 104 define a concave opening 306 therebetween, with the inter-fin spacing 408 narrowest proximal to the vertical position of the third width 416 (e.g., closer to the vertical position of the third width 416 relative to vertical positions of the first width 410 or the second width 412). In some embodiments, the spacing 408 between the pair of channel structures 104 decreases monotonically. More particularly, for the depicted symmetrical sidewalls 406, the first width 410 and the second width 412 are less than the third width 416. In some embodiments, the first width 410 is equal to the second width 412. Accordingly, a width of the opening 306 (e.g., inter-fin spacing 408) can be greatest at a same vertical dimension of the first width 410 or the second width and least at the same vertical dimension as the third width 416. The width of the opening 306 proximal to the first width 410 and the second width 412 can be equal to one another, or the opening can be greater proximal to one of the first width 410 or the second width 412 relative to the other of the first width 410 or the second width 412.

Such a geometry of the opening 306 can cause the formation of voids 204 and a remaining portion of a spacer material 302 therein within a wider portion of the bottom third of the channel structures 104, incident to a kink formed from the spacing at another portion (e.g., a medial portion) of the channel structures 104.

Relative to FIG. 5, the reduced height 404 of the spacer material 302 can provide a greater portion of the sidewalls 406 above the remaining portion of a spacer material 302. Accordingly, where the spacer material 302 is not removed, an active gate deposited over the spacer material 302 can benefit from increased contact area with the channel structures 104. However, it may prove more challenging to remove the spacer material 302, according to some techniques. Still, according to the negative taper of the lower portion of the channel structures 104, the sidewall 406 may be etched, according to an (even slightly) isotropic process, such that even if the area directly below the spacer is not removed, an active gate structure may adhere to the full length of the sidewalls.

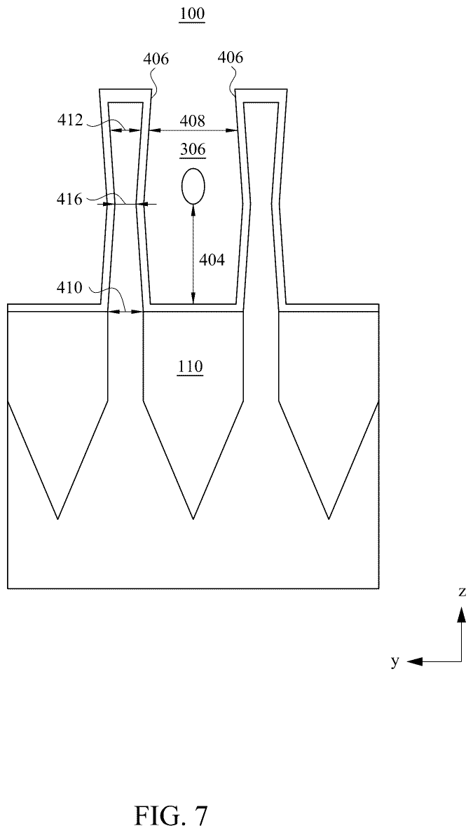

Referring now to FIG. 7, sidewalls 406 of channel structures 104 define a convex opening 306 therebetween, with the inter-fin spacing 408 widest proximal to the vertical position of the third width 416 (e.g., closer to the vertical position of the third width 416 relative to vertical positions of the first width 410 or the second width 412). In some embodiments, the spacing 408 between the pair of channel structures 104 increases monotonically from each of the vertical positions of the first width 410 and the second width 412 towards the third width 416. More particularly, for the depicted symmetrical sidewalls 406, the first width 410 and the second width 412 are greater than the third width 416. Accordingly, a width of the opening 306 (e.g., inter-fin spacing 408) can be greatest at a same vertical dimension of the third width 416, and least at the same vertical dimension as the first width 410 and the second width 412.

Such a geometry of the opening 306 can cause the formation of voids 204 and a remaining portion of a spacer material 302 slightly above the medial (e.g., halfway between) portion of the channel structures 104, incident to a kink formed from the decreasing spacing 408 between the medial portion of the upper portion of the channel structures 104. For example, the spacer material 302 may be disposed closer to the vertical position corresponding to the third width 416 than the vertical portion corresponding to the second width 412.

Relative to FIG. 6, the increased height of the channel structures 104 can provide a greater opportunity to flush or otherwise remove the spacer material 302 for the same reasons described with regard to FIG. 4. Further, the spacer material 302 can form away from either of the base of the opening, and an upper surface thereof, as may avoid interfering with further operations.

Referring now to FIG. 8, the sidewalls 406 of channel structures 104 defining an opening 306 therebetween exhibit positive taper, so that the opening 306 is wider at the top than at the bottom. In some embodiments, the spacing 408 between the pair of channel structures 104 increases monotonically from bottom to top. More particularly, for the depicted symmetrical sidewalls 406, the first width 410 and the third width 416 are greater than the second width 412. The second width 412 is also greater than the third width 416. Accordingly, a first width of the opening (e.g., inter-fin spacing 408) can be greatest at a same vertical dimension of the second width, least at the same vertical dimension as the first width 410 and medial at the same vertical dimension as the third width 416.

Such a geometry of the opening 306 can cause the formation of voids 204 and a remaining portion of a spacer material 302 therein within a wider portion, as the deposition of the gate material 106 kinks off the void during a fill process. That is, the height 404 of the remaining portion of a spacer material 302 can be disposed between the vertical height for the third width 416 and the vertical height for the second width 412. In some embodiments, such a void 204 or spacer material 302 may form vertically above the channel structures 104 (e.g., vertically above the second width 412) or may not be formed at all. In some embodiments, voids formed above the channel structures 104 are removed according to a mechanical process (e.g., chemical mechanical grinding or polishing, CMP/G). Further, voids formed may be smaller, at least according to a lateral dimension, since no kink is formed via the deposition.

The smaller voids can reduce a masking effect for portions of the dummy gate structure 202 below the spacer material 302. For example, an entrant angle of an etchant is reduced, relative to FIGS. 4-7. Further, since the height 404 for the spacer material 302 is larger, and the spacer material 302 may be dimensionally smaller, it may be more likely to flush or otherwise remove the spacer material 302 during removal of the dummy gate structure 202, relative to the spacer material of FIGS. 4-7, according to some techniques (e.g., chamber etchant or separate flushing processes, such as N_{2 or} O₂ purges/passivation operations). Further, the reduced size of the spacer material 302, relative to other approaches, can aid in electrically coupling an active gate to the channel regions (e.g., to a gate oxide therefor), since the smaller size will interfere over a smaller portion of the channel structure 104, if the spacer material 302 is not removed.

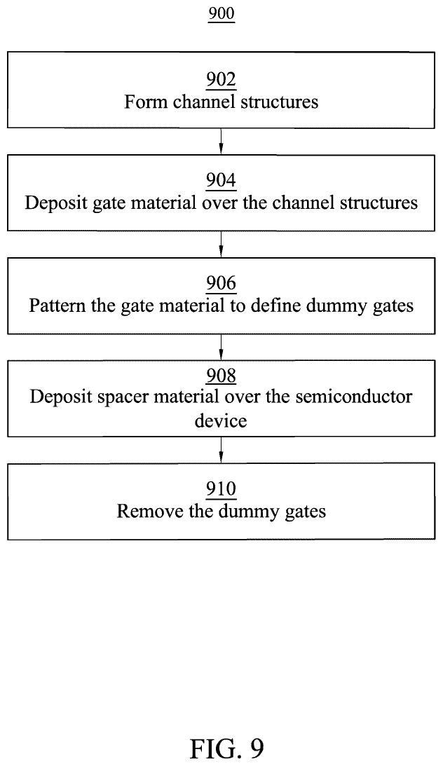

FIG. 9 illustrates a flow chart for a method 900 for fabricating a semiconductor device 100, in accordance with some embodiments. As indicated above, at least some of the operations described in the method 900 may result in the semiconductor devices 100 depicted in FIGS. 1-8. Further, some operations may only be described briefly herein, however, one skilled in the art will understand that the disclosed operations may be performed in conjunction with other disclosed methods disclosed herein, or generally known in the art. Further, the order of the disclosed operations is not intended to be limiting; certain operations may be performed in a different sequence, and still further operations may be sequenced with appropriate modifications thereto.

At operation 902 of the method 900, a pair of channel structures 104 is formed with oppositely disposed sidewalls 406, a vertical profile of the sidewalls 406 configured to modulate a position of a first void 108 in a gate material 106 deposited thereover. In some embodiments, the opposite sidewalls 406 of the pair of channel structures 104 can define further locations for gate materials 106 (and voids 108). For example, the pair of channel structures 104 can be two of numerous (e.g., hundreds, millions, etc.) channel structures 104 of a semiconductor device 100. As described above, the channel structures 104 may be formed according to various processes, and can include various channel structure 104 types. For example, some of the types discussed herein include fins of a FinFET device and nanostructures of a GAAFET, though the presentation of such illustrative examples should not be construed as limiting.

At operation 904 of the method 900, a gate material 106 is deposited over the channel structures 104, the gate material enveloping the first void 108. That is, the gate material 106 can first form the void 108, such as via self-adhesion in the high aspect ratio opening between the channel structures 104, forming a kink for prevent a complete fill. Second, the gate material 106 can continue to form over the void to fill remaining portions, so that the void 108 (e.g., trench) is enveloped about the first lateral direction (X).

At operation 906 of the method 900, the gate material 106 is patterned along a second lateral direction (Y) perpendicular to the first lateral direction (X), the gate material 106 to form a plurality of dummy gate structures 202 including second voids 204 corresponding to portions of the first void 108. That is, the combination of the gate material 106 and the first void 108 can be segmented into dummy gate structures 240, at least a portion of which include second voids 204 (e.g., a segment of the trench void 108 of operation 904). Although the void 108 of operation 904 was enveloped by the gate material 106, the patterning can expose opposite ends of the voids 204 to openings 210 formed via the patterning (e.g., as depicted in FIG. 2).

At operation 908 of the method 900, a spacer material is deposited over the semiconductor device 100, and into the second voids 204. The spacer material varies from the gate material 106, such that a removal process for the gate material 106 is less selective to the spacer material. The spacer may include a dielectric. The spacer material can include, for example, an etch stop layer, oxide layer (e.g., gate oxide), or ILD. In some embodiments, the spacer can include multiple materials. For example, where a blanket layer of a hardmask spacer is deposited into the opening 210 and an ILD is formed thereover, a portion of both of the hardmask and ILD can form into the voids 204.

At operation 910 of the method 900, the dummy gate structures 202 are removed to form openings 306 defined by the spacer material, the openings 306 including a remaining portion of the spacer material 302. In some embodiments, the spacer material is not removed. For example, an active gate may be formed over the remaining portion of the spacer material 302 (along with any remaining gate material 106 of the removed dummy gate structure 202). In such embodiment, the performance and longevity of the semiconductor device 100 can vary according to a junction between the active gate and the channel structures 104. For example, the junction, as may include a gate oxide, can vary according to a surface area, or shape (e.g., some shapes may exhibit risks for electromigration).

In some embodiments, the remaining portion of the spacer material 302 is removed during a purge process, such as a nitrogen or oxygen flush. For example, subsequent to the remaining portion of the spacer material 302 remaining disposed within the opening 306, an etchant or other removal process can be continued or modulated to remove a portion of the gate material 106 of the dummy gate structures 202 coupled with the remaining spacer material 302 (e.g., under etch). Such a process may, but need not deviate from a process to remove other portions of the dummy gate structure (e.g., a selected etchant or quantity thereof, environmental conditions, or so forth). An active gate may be formed in the opening subsequent to the removal of the remaining spacer material 302.

In some aspects, the techniques described herein relate to a method including: forming, along a first lateral direction of a semiconductor device, a pair of channel structures with oppositely disposed sidewalls, a vertical profile of the sidewalls configured to modulate a position of a first void in a gate material deposited thereover; depositing the gate material over the channel structures, the gate material enveloping the first void; patterning, along a second lateral direction perpendicular to the first lateral direction, the gate material to form a plurality of dummy gate structures including a plurality of second voids corresponding to portions of the first void; depositing a spacer material over the semiconductor device, and into the plurality of second voids; removing the dummy gate structures to form openings defined by the spacer material, the openings including a remaining portion of the spacer material; and forming, in the opening, an active gate structure.

In some aspects, the techniques described herein relate to a method including: forming, along a first lateral direction of a semiconductor device, a plurality of channel structures, the channel structures symmetric across a second lateral direction perpendicular to the first lateral direction; depositing a gate material over the channel structures, the gate material defining a first void and abutting sidewalls of the plurality of channel structures at a junction of the channel structures and the gate material. The channel structures extends a first distance along the second lateral direction at a first vertical position disposed along a surface of a lateral plane including an upper surface of an STI region. The channel structures extends a second distance along the second lateral direction at a second vertical position higher than the first vertical position and within five nm of the upper surface of the channel structure. The channel structures extends a third distance, different from at least one of the first distance or the second distance, along the second lateral direction at a third vertical position between the first vertical position and the second vertical position. The method includes depositing a spacer material over the semiconductor device to occupy a void in the gate material.

In some aspects, the techniques described herein relate to a method including: forming, along a first lateral direction of a semiconductor device, a plurality of channel structures, the channel structures symmetric across a second lateral direction perpendicular to the first lateral direction; depositing a gate material over the channel structures, the gate material defining a void. A spacing between adjacent channel structures extends a first distance at a first vertical position disposed along a surface of a lateral plane including an upper surface of an STI region. A spacing between a second vertical position within five nm of the upper surface of the channel structure of the adjacent channel structures, extends a second distance. A spacing between a third vertical position of the adjacent channel structures, the third vertical position being between the first vertical position and the second vertical position, extends a third distance, different from at least one of the first distance or the second distance. The method includes depositing a spacer material over the semiconductor device to occupy the void in the gate material.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a pair of channel structures with oppositely disposed sidewalls along a first lateral direction of a semiconductor device, a vertical profile of the sidewalls configured to modulate a position of a first void in a gate material deposited thereover;
depositing the gate material over the channel structures, the gate material enveloping the first void;
patterning, along a second lateral direction perpendicular to the first lateral direction, the gate material to form a plurality of dummy gate structures comprising a plurality of second voids corresponding to portions of the first void;
depositing a spacer material over the semiconductor device, and into the plurality of second voids; and
removing the dummy gate structures to form openings defined by the spacer material, the openings comprising a remaining portion of the spacer material.

2. The method of claim 1, further comprising:
flushing the remaining portion of the spacer material from the openings prior to forming an active gate structure; and
forming the active gate structure in the opening.

3. The method of claim 1, wherein the channel structures are symmetrical about the second lateral direction.

4. The method of claim 1, wherein:
a first distance between the pair of channel structures at a first vertical position within five nanometers of an upper surface of the channel structures is greater than:
a second distance at a second vertical position at a lower surface of a junction of the dummy gate structure and the channel structures; and
a third distance at a third vertical position disposed halfway between the first vertical position and the second vertical position; and
the second distance is less than the third distance.

5. The method of claim 1, wherein a distance between the pair of channel structures decreases monotonically between a first vertical position within five nanometers of an upper surface of the channel structures and a second vertical position at a lower surface of a junction of the dummy gate structure and the channel structures.

6. The method of claim 1, wherein:
the channel structures consist substantially of silicon;
the channel structures extend along the second lateral direction between about six and about one-hundred nanometers;
the sidewalls of the channel structures in contact with the dummy gate structure extend, vertically, between about thirty nanometers and about one hundred nanometers; and
the opening extends between about ten nanometers and about seventy nanometers along the second lateral direction.

7. The method of claim 1, wherein:
the channel structures consist substantially of silicon and germanium;
the channel structures extend along the second lateral direction between about six and about one hundred nanometers;
the sidewalls of the channel structures in contact with the dummy gate structure extend vertically between about thirty nanometers and about one-hundred nanometers; and
the opening extends between about ten nanometers and about seventy nanometers along the second lateral direction.

8. The method of claim 1, wherein:
the channel structures comprise silicon comprising nanosheets and silicon-germanium comprising nanosheets;
the channel structures extend along the second lateral direction between about six and about one hundred nanometers;
the sidewalls of the channel structures in contact with the dummy gate structure extend vertically between about thirty nanometers and about one-hundred nanometers; and
the opening extends between about ten nanometers and about seventy nanometers along the second lateral direction.

9. The method of claim 1, wherein the remaining portion of the spacer material extends less than ten nanometers along the second lateral direction.

10. The method of claim 1, wherein:
the gate material is amorphous silicon;
a substrate comprises silicon in a (100) or (110) crystallographic orientation; and
the spacer material comprises Silicon Nitride (SiN), Silicon Oxycarbide Nitride (SiCON), or Silicon Carbonitride (SiCN).

11. A method comprising:
forming a plurality of channel structures along a first lateral direction of a semiconductor device, the channel structures being symmetric across a second lateral direction perpendicular to the first lateral direction;
depositing a gate material over the channel structures, the gate material defining a void and abutting sidewalls of the plurality of channel structures at a junction of the channel structures and the gate material, wherein the channel structures extends:
a first distance along the second lateral direction at a first vertical position disposed along a surface of a lateral plane including an upper surface of an STI region;
a second distance along the second lateral direction at a second vertical position higher than the first vertical position and within five nm of an upper surface of the channel structure; and
a third distance, different from at least one of the first distance or the second distance, along the second lateral direction at a third vertical position between the first vertical position and the second vertical position; and
depositing a spacer material over the semiconductor device to occupy the void in the gate material.

12. The method of claim 11, further comprising:
removing the gate material to form an opening; and
forming an active gate structure in the opening subsequent to flush a remaining portion of the spacer material from the opening.

13. The method of claim 12, wherein:
the channel structures extend along the second lateral direction between about six and about one-hundred nanometers;
the sidewalls of the channel structures are in contact with the gate material for a vertical distance of between about thirty nanometers and about one-hundred nanometers; and
a dimension of the opening along the second lateral direction is between about ten nanometers and about seventy nanometers.

14. The method of claim 11, wherein:
the gate material is amorphous silicon;
a substrate comprises silicon in a (100) or (110) crystallographic orientation; and
the spacer material comprises Silicon Nitride (SiN), Silicon Oxycarbide Nitride (SiCON), or Silicon Carbonitride (SiCN).

15. The method of claim 11, wherein:
the first distance is greater than the second distance and the third distance;
the second distance is greater than the third distance; and
the spacer material occupying the void is formed above the third vertical position.

16. A method comprising:
forming a plurality of channel structures along a first lateral direction of a semiconductor device, the channel structures being symmetric across a second lateral direction perpendicular to the first lateral direction;
depositing a gate material over the channel structures, the gate material defining a void, wherein:
a spacing between adjacent channel structures extends a first distance at a first vertical position disposed along a surface of a lateral plane including an upper surface of an STI region;
a spacing between a second vertical position within five nm of an upper surface of the channel structure of the adjacent channel structures, extends a second distance; and
a spacing between a third vertical position of the adjacent channel structures, the third vertical position being between the first vertical position and the second vertical position, extends a third distance, different from at least one of the first distance or the second distance; and
depositing a spacer material over the semiconductor device to occupy the void in the gate material.

17. The method of claim 16, wherein:
the third distance is greater than the first distance and the second distance; and
the spacer material occupying the void is formed vertically between the first vertical position and the third vertical position.

18. The method of claim 16, wherein:
the third distance is less than the first distance and the second distance; and
the spacer material occupying the void is formed vertically closer to the third vertical position than the first vertical position or the second vertical position.

19. The method of claim 16, wherein:
the first distance is greater than the second distance and the third distance;
the second distance is greater than the third distance; and
the spacer material occupying the void is formed between the first vertical position and the third vertical position.

20. The method of claim 16, wherein:
the first distance is less than the second distance and the third distance;
the second distance is less than the third distance; and
the spacer material occupying the void is formed above the third vertical position.
